(19) United States
(12) Patent Application Publication
(10) Pub. No.: US 2023/0244144 A1
(43) Pub. Date: Aug. 3, 2023

(54) POSITIVE-TYPE PHOTOSENSITIVE RESIN COMPOSITION AND CURED FILM PREPARED THEREFROM

(71) Applicant: ROHM AND HAAS ELECTRONIC MATERIALS KOREA LTD., Chungcheongnam-do (KR)

(72) Inventors: Jung-Hwa LEE, Gyeonggi-do (KR); Jong-Ho NA, Gyeonggi-do (KR); Geun HUH, Gyeonggi-do (KR)

(21) Appl. No.: 18/070,893

(22) Filed: Nov. 29, 2022

(30) Foreign Application Priority Data
Dec. 30, 2021 (KR) 10-2021-0193255

(51) Int. Cl. G03F 7/039; G03F 7/075; C08G 77/18

(52) U.S. Cl. CPC G03F 7/0395; C08G 77/18; G03F 7/0757; C08G 77/80

(57) ABSTRACT

The present invention relates to a positive-type photosensitive resin composition and to a cured film prepared therefrom The positive-type photosensitive resin composition comprises an acid-modified epoxy acrylate resin of a specific structure, so that it can provide a cured film that is excellent in flexible characteristics while having excellent film retention rate and sensitivity.

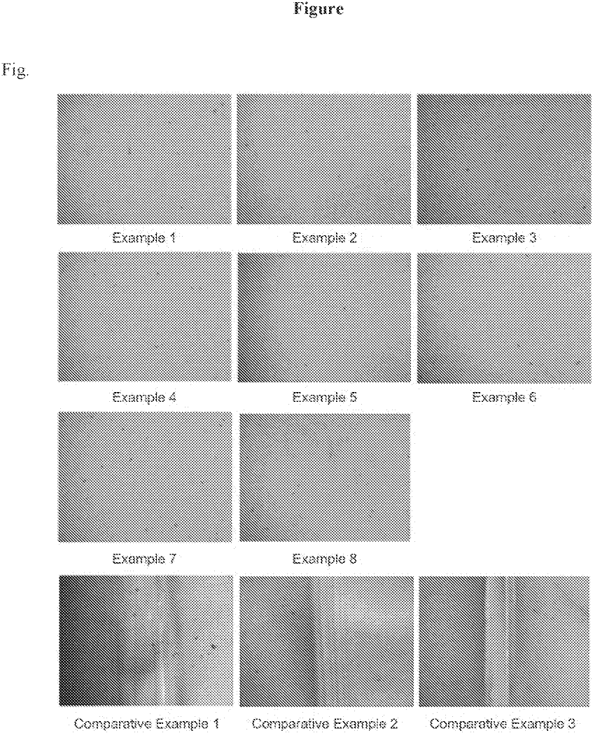

### TECHNICAL FIELD

The present invention relates to a positive-type photosensitive resin composition and to a cured film prepared therefrom. Specifically, the present invention relates to a positive-type photosensitive resin composition capable of forming a cured film (insulation film) having flexible characteristics while having an excellent film retention rate and sensitivity.

### BACKGROUND ART

Positive-type photosensitive resin compositions capable of forming a specific pattern through relatively fewer steps are used in the preparation of a cured film (insulation film) to be adopted in a liquid crystal display, an organic EL display, and the like.

However, a cured film prepared from a conventional positive-type photosensitive resin composition has a problem in that its sensitivity is lower than that of a cured film prepared from a negative-type photosensitive resin composition. That is, when a cured film is formed from a photosensitive resin composition and subjected to exposure and development steps to form an insulation film having a fine pattern of a specific shape, a cured film formed from a positive-type photosensitive resin composition has a low sensitivity, resulting in difficulties in achieving a fine pattern.

In order to increase the sensitivity of a positive-type photosensitive resin composition, various photoactive compounds have been tried (see Patent Document 1). However, a cured film prepared from such a positive-type photosensitive resin composition has a large loss in thickness during the development step, which causes a limit in obtaining the film retention rate and resolution to a required level.

Meanwhile, as interest is focused on the development of liquid crystal displays and organic EL displays having flexible characteristics in recent years, it is required to increase the flexible characteristics of materials constituting these displays. Accordingly, it is necessary to develop a positive-type photosensitive resin composition capable of enhancing the flexible characteristics of a cured film, which is one of the above materials.

### PRIOR ART DOCUMENT

(Patent Document 1) Korean Laid-open Patent Publication No. 2017-0062273

### DISCLOSURE OF INVENTION

### Technical Problem

In order to solve the above-mentioned problems in the art, the present inventors have conducted various studies. As a result, it has been discovered that if an acid-modified epoxy acrylate resin of a specific structure is introduced into a positive-type photosensitive resin composition, it is possible to obtain a cured film that is excellent in sensitivity and film retention rate as well as in flexible characteristics.

Accordingly, the present invention aims to provide an improved positive-type photosensitive resin composition and a cured film prepared therefrom and having excellent sensitivity, film retention rate, and flexible characteristics.

### Solution to Problem

In order to accomplish the above object, the present invention provides a positive-type photosensitive resin composition, which comprises (A) a siloxane copolymer; (B) a resin comprising a structural unit represented by the following Formula 1; (C) a photoactive compound; and (D) a solvent:

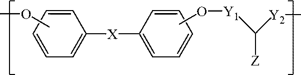

in Formula 1,
X is a substituted or unsubstituted C₁₋₆ aliphatic structure,
Y₁ and Y₂ are each independently a substituted or unsubstituted C₁₋₆ alkylene group or a substituted or unsubstituted C₄₋₁₀ cycloalkylene group, and
Z is hydrogen, a substituted or unsubstituted C₁₋₆ alkyl group, or a substituent represented by the following Formula 1a,

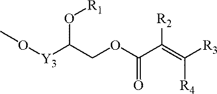

in Formula 1a,
Y₃ is a substituted or unsubstituted C₁₋₆ alkylene group or a substituted or unsubstituted C₄₋₁₀ cycloalkylene group,
R₁ is hydrogen or a substituent represented by the following Formula 1b, and
R₂ to R₄ are each independently hydrogen, a substituted or unsubstituted C₁₋₁₀ alkyl group, or a substituted or unsubstituted C₆-₁₅ aryl group,

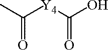

in Formula 1b,
Y₄ is a substituted or unsubstituted C₁₋₆ alkylene group or a substituted or unsubstituted C₄₋₁₀ cycloalkylene group.
In addition, the present invention provides a cured film formed from the positive-type photosensitive resin composition.

### ADVANTAGEOUS EFFECTS OF INVENTION

The present invention can provide a cured film that is excellent in flexible characteristics by introducing an acid-modified epoxy acrylate resin having a specific structure (Formula 1) into a positive-type photosensitive resin composition. In addition, the present invention can provide a cured film that is excellent in sensitivity, film retention rate, and resolution by introducing a photopolymerizable compound containing a double bond into a positive-type photosensitive resin composition.

Accordingly, the positive-type photosensitive resin composition according to the present invention can be advantageously used for forming an insulation film to be adopted in a liquid crystal display, an organic EL display, and the like having flexible characteristics.

### BRIEF DESCRIPTION OF DRAWINGS

The FIGURE shows images of the cured films each bonded to a polyimide film in Test Example 2 to visually observe cracks after its flexible characteristics were evaluated.

### BEST MODE FOR CARRYING OUT THE INVENTION

Hereinafter, the present invention will be described in detail. However, the present invention is not limited to those described below. Rather, it can be modified into various forms as long as the gist of the invention is not altered.

In addition, throughout the description of the embodiments, the term “comprise” means that other elements may be included unless otherwise indicated. In addition, all numbers and expressions relating to quantities of components, reaction conditions, and the like used herein may be understood as being modified by the term “about” unless specifically stated otherwise.

### Positive-Type Photosensitive Resin Composition

The present invention relates to a positive-type photosensitive resin composition (hereinafter, to be referred to as “photosensitive resin composition”). The photosensitive resin composition comprises (A) a siloxane copolymer; (B) a resin comprising a structural unit represented by Formula 1; (C) a photoactive compound; and (D) a solvent, which is explained in detail, as follows.

### (A) Siloxane Copolymer

The photosensitive resin composition according to the present invention comprises a siloxane copolymer (or polysiloxane) (A).

The siloxane copolymer comprises a structure derived from a hydrolysate of a silane compound and/or a condensate thereof. In such an event, the silane compound may be any of monofunctional to tetrafunctional silane compounds.

As a result, the siloxane copolymer may comprise at least one type of siloxane structural units selected from the following Q, T, D, and M types:
Q type siloxane structural unit: a siloxane structural unit comprising a silicon atom and four adjacent oxygen atoms, which may be derived from, for example, a tetrafunctional silane compound or a hydrolysate of a silane compound that has four hydrolyzable groups.
T type siloxane structural unit: a siloxane structural unit comprising a silicon atom and three adjacent oxygen atoms, which may be derived from, for example, a trifunctional silane compound or a hydrolysate of a silane compound that has three hydrolyzable groups.
D type siloxane structural unit: a siloxane structural unit comprising a silicon atom and two adjacent oxygen atoms (i.e., a linear siloxane structural unit), which may be derived from, for example, a difunctional silane compound or a hydrolysate of a silane compound that has two hydrolyzable groups.
M type siloxane structural unit: a siloxane structural unit comprising a silicon atom and one adjacent oxygen atom, which may be derived from, for example, a monofunctional silane compound or a hydrolysate of a silane compound that has one hydrolyzable group.

Specifically, the siloxane copolymer comprises a structural unit derived from two types of a silane compound represented by the following Formula 2. For example, the siloxane copolymer may be a hydrolysate of two types of a silane compound represented by the following Formula 2 and/or a condensate thereof.

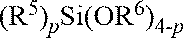

in Formula 2,
p is an integer of 0 to 3,
R⁵ is each independently a C₁₋₁₂ alkyl group, a C₂₋₁₀ alkenyl group, a C₆₋₁₅ aryl group, a 3- to 12-membered heteroalkyl group, a 4- to 10-membered heteroalkenyl group, or a 6- to 15-membered heteroaryl group; and R⁶is each independently hydrogen, a C₁₋₅ alkyl group, a C₂₋₆ acyl group, or a C₆₋₁₅ aryl group, and the heteroalkyl, the heteroalkenyl, and the heteroaryl groups each independently have at least one heteroatom selected from the group consisting of N, O, and S.

In Formula 2, the compound may be a tetrafunctional silane compound where p is 0, a trifunctional silane compound where p is 1, a difunctional silane compound where p is 2, or a monofunctional silane compound where p is 3.

The silane compound may specifically be, as the tetrafunctional silane compound, tetraacetoxysilane, tetramethoxysilane, tetraethoxysilane, tetrabutoxysilane, tetraphenoxysilane, tetrabenzyloxysilane, or tetrapropoxysilane, as the trifunctional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d3-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1 -(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, or 3-trimethoxysilylpropylsuccinic acid, as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, or dimethoxydi-p-tolylsilane, and as the monofunctional silane compound, trimethylsilane, tributylsilane, trimethylmethoxysilane, tributylethoxysilane, (3-glycidoxypropyl)dimethylmethoxysilane, or (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

The conditions for obtaining a hydrolysate of the silane compound of the above Formula 2 or a condensate thereof are not particularly limited. For example, the silane compound represented by Formula 2 is optionally diluted with a solvent, and water and an acid catalyst (e.g., hydrochloric acid, acetic acid, nitric acid, or the like) or a base catalyst (e.g., ammonia, triethylamine, cyclohexylamine, tetramethylammonium hydroxide, or the like) are added thereto, followed by stirring the mixture to obtain the desired hydrolysate or a condensate thereof.

The weight average molecular weight of the siloxane polymer (i.e., condensate) obtained by the hydrolysis polymerization of the silane compound of the above Formula 2 may be 3,000 to 20,000, 5,000 to 17,000, 6,500 to 16,000, or 7,000 to 15,000. If the weight average molecular weight is within the above range, the sensitivity and solubility of a cured film and the dissolution rate to a developer may be excellent.

The types and amounts of the solvent, acid catalyst, and base catalyst are not particularly limited.

The hydrolysis polymerization reaction may be carried out at a low temperature of 20° C. or lower. Alternatively, the reaction may be expedited by heating or refluxing. In addition, the time for the hydrolysis polymerization reaction may be appropriately adjusted according to the type, concentration, reaction temperature, and the like of the silane compound.

The siloxane copolymer may comprise a linear siloxane structural unit (i.e., D-type siloxane structural unit). This linear siloxane structural unit may be derived from a difunctional silane compound, for example, a compound represented by the above Formula 2 where p is 2. Specifically, the siloxane copolymer may comprise the structural unit derived from the silane compound of the above Formula 2 where p is 2 in an amount of 5 to 40% by mole, preferably 5 to 30% by mole, more preferably 10 to 30% by mole, relative to the number of moles of Si atoms. Within the above content range, it is possible that a cured film may have flexible characteristics while maintaining a certain level of hardness, whereby the crack resistance to an external stress and flexible characteristics can be further enhanced.

The siloxane copolymer may comprise a structural unit (i.e., siloxane structural unit of T-type) derived from a silane compound represented by the above Formula 2 where p is 1. Particularly, the siloxane copolymer may comprise the structural unit derived from the silane compound of the above Formula 2 where p is 1 in an amount of 40 to 85% by mole, preferably 50 to 80% by mole, more preferably 60 to 70% by mole, relative to the number of moles of Si atoms. Within the above content range, it is possible to increase the precision of a pattern formed on a cured film.

The siloxane copolymer may comprise a structural unit derived from a silane compound having an aryl group in view of the hardness, sensitivity, and film retention rate of a cured film. Specifically, the siloxane copolymer may comprise the structural unit derived from a silane compound having an aryl group in an amount of 30 to 70% by mole, preferably 35 to 50% by mole, more preferably 40 to 45% by mole, relative to the number of moles of Si atoms. Within the above content range, the compatibility of the siloxane copolymer with a photoactive compound (e.g., 1,2-quinonediazide compound) is excellent, which may prevent an excessive decrease in sensitivity of a cured film while enhancing the transparency of the cured film. The structural unit derived from the silane compound having an aryl group may be, for example, a structural unit derived from a silane compound of the above Formula 2 where R⁵ is an aryl group, preferably a silane compound of the above Formula 2 where p is 1 and R⁵ is an aryl group, more preferably, a silane compound of the above Formula 2 where p is 1 and R⁵ is a phenyl group (i.e., siloxane structural unit of T-phenyl type).

The siloxane copolymer may comprise a structural unit (i.e., siloxane structural unit of Q-type) derived from a silane compound represented by the above Formula 2 where p is 0. Specifically, the siloxane copolymer may comprise the structural unit derived from the silane compound of the above Formula 2 where p is 0 in an amount of 10 to 40% by mole, preferably 15 to 35% by mole, more preferably 20 to 30% by mole, relative to the number of moles of Si atoms. Within the above content range, the sensitivity and developability of a cured film can be enhanced.

The term “% by mole relative to the number of moles of Si atoms” as used herein refers to a percentage of the number of moles of Si atoms contained in a specific structural unit with respect to the total number of moles of Si atoms contained in all of the structural units constituting the siloxane polymer.

The molar content (% by mole) of a siloxane structural unit in the siloxane copolymer may be measured by the combination of Si-NMR, ¹H-NMR, ¹³C-NMR, IR, TOF-MS, elementary analysis, measurement of ash, and the like. For example, in order to measure the molar content of a siloxane structural unit having a phenyl group, an Si-NMR analysis is performed on the entire siloxane copolymer, followed by an analysis of the phenyl-bound Si peak area and the phenyl-unbound Si peak area. The molar amount can then be computed from the peak area ratio between them.

The siloxane copolymer may have an acid dissociation constant (pKₐ) of 11 or less in dimethyl sulfoxide. Specifically, the siloxane copolymer may have an acid dissociation constant of 1 to 11, 1.5 to 10, 2 to 9, 3 to 8.5, 4 to 8.0, 5 to 7.7, or 6 to 7.6, in dimethyl sulfoxide. If the acid dissociation constant of the siloxane copolymer is within the above range, it is possible to increase the precision of the pattern formed on a cured film while increasing the developability of the cured film

The amount of the siloxane copolymer may be 50% by weight to 95% by weight, 60% by weight to 90% by weight, 65% by weight to 85% by weight, or 70% by weight to 80% by weight, based on the total weight of the photosensitive resin composition excluding the balanced amount of solvents In addition, it may be 15 to 35% by weight, 16 to 32% by weight, 17 to 30% by weight, 18 to 28% by weight, or 19 to 25% by weight, based on the total weight of the photosensitive resin composition including solvents. Within the above content ranges, the developability is appropriately controlled, which can enhance the film retention rate and pattern resolution of a cured film.

The siloxane copolymer, when pre-cured, may have a dissolution rate of 50 Å/sec or more, preferably, 500 Å/sec or more, more preferably, 1,500 Å or more, in an aqueous solution of 1.5% by weight of tetramethylammonium hydroxide (TMAH). Within the above range, the high developability to a developer may secure excellent resolution. Meanwhile, the upper limit of the dissolution rate is not particularly limited. But it may be 100,000 Å/sec or less, 50,000 Å/sec or less, or 10,000 Å/sec or less.

### (B) Acid-Modified Epoxy Acrylate Resin

The photosensitive resin composition according to the present invention comprises a resin (B) comprising a structural unit represented by the following Formula 1 as an acid-modified epoxy acrylate resin. The resin comprising a structural unit represented by the following Formula 1 serves to increase the flexibility of a cured film. As the flexibility of a cured film is increased by virtue of the resin comprising a structural unit represented by Formula 1, the present invention can provide a cured film having excellent flexible characteristics.

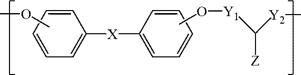

in Formula 1,
X is a substituted or unsubstituted C₁₋₆ aliphatic structure,
Y₁ and Y₂ are each independently a substituted or unsubstituted C₁₋₆ alkylene group or a substituted or unsubstituted C₄₋₁₀ cycloalkylene group, and
Z is hydrogen, a substituted or unsubstituted C₁₋₆ alkyl group, or a substituent represented by the following Formula 1a,

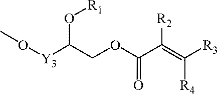

in Formula 1a,
Y₃ is a substituted or unsubstituted C₁₋₆ alkylene group or a substituted or unsubstituted C₄-₁₀ cycloalkylene group,
R₁ is hydrogen or a substituent represented by the following Formula 1b, and
R₂ to R₄ are each independently hydrogen, a substituted or unsubstituted C₁₋₁₀ alkyl group, or a substituted or unsubstituted C₆-₁₅ aryl group,

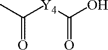

in Formula 1b,
Y₄ is a substituted or unsubstituted C₁₋₆ alkylene group or a substituted or unsubstituted C₄-₁₀ cycloalkylene group,

If the aliphatic structure, alkylene group, cycloalkylene group, alkyl group, and aryl group are substituted (if the hydrogen bonded to the carbon of each functional group is substituted), the substituent that may be bonded may be at least one selected from the group consisting of a C₁₋₅ alkyl group, a C₁₋₅ alkyloxy group, a C₃₋₁₀ cycloalkyl group, a C₆₋₁₀aryl group, and a 6- to 10-membered heteroaryl group.

Specifically, the flexibility and pattern resolution of a cured film is taken into account, in Formula 1, X is a substituted or unsubstituted C₁₋₆ alkylene group, Y₁ and Y₂ are each independently a C₁₋₃ alkylene group, and Z is a substituent represented by Formula 1a, wherein, in Formula 1a, Y₃ is a C₁₋₃ alkylene group, R₁ is a substituent represented by Formula 1b, and R₂ to R₄ are all hydrogen, and, in Formula 1b, Y₄ may be a C₄₋₇ cycloalkylene group.

More specifically, the structural unit represented by Formula 1 may be at least one selected from the group consisting of structural units represented by the following Formulae 1-1 and 1-2.

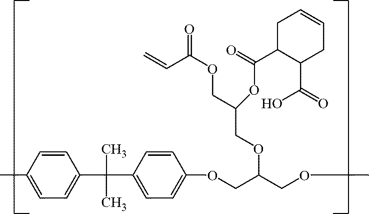

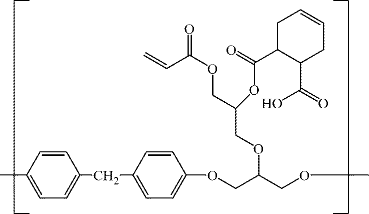

The weight average molecular weight of the resin comprising a structural unit represented by Formula 1 may be 2,000 to 18,000, preferably 5,000 to 15,000, more preferably 7,000 to 13,000. Within the above range, the flexibility of a cured film may be enhanced while the coatability of the photosensitive resin composition is secured

The content of the resin comprising a structural unit represented by Formula 1 may be 2 to 40 parts by weight, 5 to 38 parts by weight, 10 to 35 parts by weight, 15 to 32 parts by weight, 20 to 30 parts by weight, or 25 to 28 parts by weight, relative to 100 parts by weight of the siloxane copolymer (A) on the basis of solids content. In addition, it may be 0.1 to 15, 0.2 to 10% by weight, 0.3 to 8% by weight, 0.4 to 7% by weight, or 0.5 to 6% by weight, based on the total weight of the photosensitive resin composition including solvents. Within the above ranges, the flexibility and pattern resolution of a cured film may be enhanced while the coatability of the photosensitive resin composition is excellent

### (C) Photoactive Compound

The photosensitive resin composition according to the present invention comprises a photoactive compound (C) as a photoactive agent (PAC). Specifically, the photoactive compound serves to initiate the polymerization of compounds (monomers) that can be crosslinked by visible light, ultraviolet radiation, deep-ultraviolet radiation, or the like.

The photoactive compound may be a 1,2-quinonediazide-based compound. Specifically, the 1,2-quinonediazide-based compound may be an ester compound of a phenolic compound and 1,2-benzoquinonediazide-4-sulfonic acid or 1,2-benzoquinonediazide-5-sulfonic acid; an ester compound of a phenolic compound and 1,2-naphthoquinonediazide-4-sulfonic acid or 1,2-naphthoquinonediazide-5-sulfonic acid; a sulfonamide compound of a phenolic compound in which the hydroxyl group is substituted with an amino group and 1,2-benzoquinonediazide-4-sulfonic acid or 1,2-benzoquinonediazide-5-sulfonic acid; or a sulfonamide compound of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

The phenolic compound may specifically be at least one selected from the group consisting of 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1, 1′-spirobiindene-5,6,7,5′,6′,7′-hexanol, 2,2,4-trimethyl-7,2′,4′-trihydroxyflavane, and bis[4-hydroxy-3-(2-hydroxy-5-methylbenzyl)-5-dimethylphenyl]methane.

More specifically, the 1,2-quinonediazide-based compound may be an ester compound of 2,3,4-trihydroxybenzophenone and 1,2-naphthoquinonediazide-4-sulfonic acid, an ester compound of 2,3,4-trihydroxybenzophenone and 1,2-naphthoquinonediazide-5-sulfonic acid, an ester compound of 4,4′-[1-[4-[1-[4-hydroxyphenyl]-1-methylethyl]phenyl]ethylidene]bisphenol and 1,2-naphthoquinonediazide-4-sulfonic acid, an ester compound of 4,4′-[1-[4-[1-[4-hydroxyphenyl]-1-methylethyl]phenyl]ethylidene]bisphenol and 1,2-naphthoquinonediazide-5-sulfonic acid, or an ester compound of bis[4-hydroxy-3-(2-hydroxy-5-methylbenzyl)-5-dimethylphenyl]methane and 1,2-naphthoquinonediazide-5-sulfonic acid.

Preferably, the 1,2-quinonediazide-based compound may be at least one selected from the group consisting of 1,2-quinonediazide 4-sulfonic acid ester, 1,2-quinonediazide 5-sulfonic acid ester, and 1,2-quinonediazide 6-sulfonic acid ester. If the 1,2-quinonediazide-based compound is any of the compounds exemplified above, the transparency of a cured film may be further enhanced.

The content of the photoactive compound may be 2 to 50 parts by weight, 3 to 45 parts by weight, 5 to 40 parts by weight, 7 to 35 parts by weight, 9 to 30 parts by weight, or 11 to 20 parts by weight, relative to 100 parts by weight of the siloxane copolymer (A) on the basis of solids content. In addition, it may be 0.1 to 20, 0.5 to 15% by weight, 1 to 10% by weight, 1.5 to 5% by weight, or 2 to 3% by weight, based on the total weight of the photosensitive resin composition including solvents. Within the above content ranges, it is possible to prevent such defects as a rough surface of a cured film and such a pattern shape as scum appearing at the bottom portion during development.

### (D) Solvent

The photosensitive resin composition according to the present invention comprises a solvent (D). The solvent (E) serves to dissolve or disperse each component contained in the photosensitive resin composition.

Specifically, the solvent may be an organic solvent such as alcohols, ethers, glycol ethers, ethylene glycol alkyl ether acetates, diethylene glycol, propylene glycol monoalkyl ethers, propylene glycol alkyl ether acetates, propylene glycol alkyl ether propionates, aromatic hydrocarbons, ketones, or esters.

More specifically, the solvent may be methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol monomethyl ether acetate, propylene glycol monoethyl ether acetate, propylene glycol monopropyl ether acetate, dipropylene glycol methyl ether acetate, propylene glycol butyl ether acetate, toluene, xylene, methyl ethyl ketone, 4-hydroxy-4-methyl-2-pentanone, cyclopentanone, cyclohexanone, 2-heptanone, γ-butyrolactone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, or N-methylpyrrolidone. The above compounds may be used alone or in combination of two or more thereof.

Preferred as the solvent among the above may be diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol monomethyl ether acetate, methyl 2-methoxypropionate, γ-butyrolactone, or 4-hydroxy-4-methyl-2-pentanone.

The content of the solvent may be the balance excluding the contents of the respective components contained in the photosensitive resin composition. Specifically, the content of the solvent may be 10 to 90% by weight, 30 to 85% by weight, 40 to 80% by weight, or 50 to 70% by weight, based on the total weight of the photosensitive resin composition comprising the solvent.

### (E) Photopolymerizable Compound

The photosensitive resin composition according to the present invention may further comprise a photopolymerizable compound (E) comprising a double bond. The photopolymerizable compound may be a monofunctional or multifunctional ester compound having at least one ethylenically unsaturated double bond. Specifically, it may be a multifunctional compound having at least two functional groups from the viewpoint of chemical resistance of a cured film.

Specifically, the photopolymerizable compound containing a double bond may be at least one selected from the group consisting of ethylene glycol di(meth)acrylate, propylene glycol di(meth)acrylate, diethylene glycol di(meth)acrylate, triethylene glycol di(meth)acrylate, 1,6-hexanediol di(meth)acrylate, polyethylene glycol di(meth)acrylate, polypropylene glycol di(meth)acrylate, glycerin tri(meth)acrylate, trimethylolpropane tri(meth)acrylate, pentaerythritol tri(meth)acrylate, a monoester of pentaerythritol tri(meth)acrylate and succinic acid; pentaerythritol tetra(meth)acrylate, dipentaerythritol penta(meth)acrylate, dipentaerythritol hexa(meth)acrylate, a monoester of dipentaerythritol penta(meth)acrylate and succinic acid; a caprolactone-modified dipentaerythritol hexa(meth)acrytate; pentaerythritol triacrylate-hexamethylene diisocyanate (a reaction product of pentaerythritol triacrylate and hexamethylene diisocyanate); tripentaerythritol hepta(meth)acrylate; tripentaerythritol octa(meth)acrylate; bisphenol A epoxyacrylate; and ethylene glycol monomethyl ether acrylate.

Examples of the photopolymerizable compound may include (i) monofunctional (meth)acrylate such as Aronix M-101, M-1 1 1, and M-114 manufactured by Toagosei Co., Ltd., KAYARAD T4-110S and T4-120S manufactured by Nippon Kayaku Co., Ltd., and V-158 and V-2311 manufactured by Osaka Yuki Kayaku Kogyo Co., Ltd.; (ii) bifunctional (meth)acrylate such as Aronix M-210, M-240, and M-6200 manufactured by Toagosei Co., Ltd., KAYARAD HDDA, HX-220, and R-604 manufactured by Nippon Kayaku Co., Ltd., and V-260, V-312, and V-335 HP manufactured by Osaka Yuki Kayaku Kogyo Co., Ltd.; and (iii) tri- and higher functional (meth)acrylate such as Aronix M-309, M-400, M-403, M-405, M-450, M-7100, M-8030, M-8060, and TO-1382 manufactured by Toagosei Co., Ltd., KAYARAD TMPTA, DPHA, DPHA-40H, DPCA-20, DPCA-30, DPCA-60, and DPCA-120 manufactured by Nippon Kayaku Co., Ltd., and V-295, V-300, V-360, V-GPT, V-3PA, V-400, and V-802 manufactured by Osaka Yuki Kayaku Kogyo Co, Ltd.

The content of the photopolymerizable compound may be 0.1 to 20 parts by weight, 0.5 to 15 parts by weight, 1 to 12 parts by weight, 1.5 to 8 parts by weight, 2 to 7 parts by weight, or 2.2 to 6.5 parts by weight, relative to 100 parts by weight of the siloxane copolymer (A) on the basis of solids content. In addition, it may be 0.1 to 10, 0.2 to 8% by weight, 0.3 to 5% by weight, 0.4 to 4% by weight, or 0.5 to 2% by weight, based on the total weight of the photosensitive resin composition including solvents. Within the above content ranges, it is excellent in developability and has adequate flowability during post-bake (i.e., a flow takes place properly), so that a pattern having a desired taper angle can be formed.

### (F) Epoxy Compound

The photosensitive resin composition according to the present invention may further comprise an epoxy compound (F). The epoxy compound acts to increase the internal density of the siloxane copolymer (A), which may enhance the chemical resistance of a cured film. The epoxy compound may be a homo-oligomer or a hetero-oligomer of an unsaturated monomer containing at least one epoxy group.

The unsaturated monomer containing at least one epoxy group may specifically be glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, glycidyl methacrylate may be used.

The epoxy compound may be synthesized by any methods commonly known.

The epoxy compound may further comprise the following structural unit.

Specifically, the additional structural unit may be a structural unit derived from a compound such as styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; p-hydroxy-α-methylstyrene; acetylstyrene; an ethylenically unsaturated compound containing an aromatic ring such as divinylbenzene, vinylphenol, o-vinylbenzyl methyl ether, m-vinylbenzyl methyl ether, p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxydiethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, N-cyclohexylmaleimide, and the like

The additional structural unit derived from the above compounds may be contained in the epoxy compound alone or in combination of two or more thereof. An additional structural unit derived from the styrene compounds among the above is preferred from the viewpoint of polymerizability.

Meanwhile, it may be preferable from the viewpoint of chemical resistance of a cured film that the epoxy compound does not contain a structural unit derived from a compound having a carboxyl group among the above compounds.

The epoxy compound may comprise the above additional structural unit in an amount of 0 to 70% by mole, preferably 10 to 60% by mole, based on the total number of moles of the structural units constituting the epoxy compound. Within the above content range, it is possible to secure the hardness of a cured film at a required level.

The weight average molecular weight of the epoxy compound may be 100 to 30,000, preferably, 1,000 to 15,000, more preferably, 5,000 to 10,000. Within the above range, a cured film may have high hardness with a uniform thickness, which may be suitable for planarizing any steps.

The content of the epoxy compound may be 0.1 to 50 parts by weight, 2 to 45 parts by weight, 3 to 40 parts by weight, 10 to 38 parts by weight, 15 to 35 parts by weight, or 25 to 30 parts by weight, relative to 100 parts by weight of the siloxane copolymer (A) on the basis of solids content. In addition, it may be 0.1 to 20, 0.5 to 15% by weight, 1 to 10% by weight, 2 to 8% by weight, or 5 to 7% by weight, based on the total weight of the photosensitive resin composition including solvents. Within the above content ranges, the sensitivity and chemical resistance of a cured film can be enhanced.

### (G) Surfactant

The photosensitive resin composition according to the present invention may further comprise a surfactant (G). The surfactant serves to enhance the coatability of the photosensitive resin composition and may be fluorine-based surfactants, silicon-based surfactants, or non-ionic surfactants.

The surfactant may specifically be fluorine- and silicon-based surfactants such as FZ-2122 supplied by Dow Coming Toray Co., Ltd., BM-1000 and BM-1 100 supplied by BM CHEMIE Co., Ltd., Megapack F-142 D, F-172, F-173, and F-183 supplied by Dai Nippon Ink Chemical Kogyo Co, Ltd., Florad FC-135, FC-170 C, FC-430, and FC-431 supplied by Sumitomo 3M Ltd., Sufron S-112, S-113, S-131, S-141, S-145, S-382, SC′.-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; or organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.). The above compounds may be used alone or in combination of two or more thereof.

The content of the surfactant may be 0.001 to 5 parts by weight, 0.005 to 4 parts by weight, 0.01 to 3 parts by weight, 0.05 to 2.5 parts by weight, 0.1 to 2 parts by weight, or 0.2 to 1 part by weight, relative to 100 parts by weight of the siloxane copolymer (A) on the basis of solids content. In addition, it may be 0.0001 to 3, 0.001 to 2.5% by weight, 0.01 to 2% by weight, 0.05 to 1% by weight, or 0.07 to 0.5% by weight, based on the total weight of the photosensitive resin composition including solvents. Within the above content ranges, the photosensitive resin composition may have excellent coatability.

The photosensitive resin composition according to the present invention may further comprise commonly known adhesion aids, defoamers, viscosity modifiers, dispersants, or the like within the range that does not affect the physical properties thereof.

### Cured Film

The present invention provides a cured film formed from the photosensitive resin composition described above.

The cured film according to the present invention may be formed by a method commonly known, for example, a method in which the photosensitive resin composition is coated onto a substrate and then cured. Specifically, the photosensitive resin composition is coated on a substrate and subjected to pre-bake at a temperature of 60 to 130° C. to remove solvents, then exposed to light using a photomask having a desired pattern; and subjected to development using a developer (for example, a tetramethylammonium hydroxide (TMAH) solution) to form a pre-baked film having a pattern formed thereon. Thereafter, if necessary, the pre-baked film having a pattern is subjected to post-bake at a temperature of 150 to 300° C. for 10 minutes to 5 hours to prepare a desired cured film.

The exposure to light may be carried out at an exposure dose of 10 to 200 mJ/cm2 based on a wavelength of 365 nm in a wavelength band of 200 to 500 nm. In addition, as a light source used for the exposure, a low-pressure mercury lamp, a high-pressure mercury lamp, an extra high-pressure mercury lamp, a metal halide lamp, an argon gas laser, or the like may be used. X-rays, electronic rays, or the like may also be used, if desired.

The method of coating the photosensitive resin composition onto a substrate may be a spin coating, a slit coating, a roll coating, a screen printing, an applicator, or the like. A coating film in a desired thickness of, for example, 2 to 25 µm may be prepared by this method.

Since the present invention prepares (forms) a cured film from the photosensitive resin composition described above, it is possible to provide a cured film having excellent thermal resistance, transparency, dielectric constant, chemical resistance, and flexible characteristics (resistance to cracking), along with a high sensitivity and film retention rate.

Accordingly, the cured film according to the present invention can be advantageously applied to such fields as electricity, electronics, or optics. In particular, a cured film according to the present invention has excellent flexible characteristics that can minimize the occurrence of cracks even upon repeated bending, thus, it can be advantageously used as a material (e.g, a pixel defining film) of a liquid crystal display or organic EL display having flexible characteristics.

### MODE FOR THE INVENTION

Hereinafter, the present invention will be described in more detail with reference to the following examples. But the following Examples are intended to further illustrate the present invention without limiting its scope.

In the following synthesis examples, the weight average molecular weight is determined by gel permeation chromatography (GPC, eluent: tetrahydrofuran) referenced to a polystyrene standard.

In addition, the acid dissociation constant (pKₐ) appearing in the Synthesis Example is a value calculated through potentiometric titration using a potentiometric automatic titration device (AT-710M; manufactured by Kyoto Denshi Kogyo Co., Ltd.), 0.1 mole/L sodium hydroxide/ethanol solution as a titration reagent, and dimethyl sulfoxide as a titration solvent.

### [Synthesis Example 1] Preparation of a Siloxane Copolymer (A-1)

A reactor equipped with a reflux condenser was charged with 58.9 parts by weight of phenyltrimethoxysilane, 19.5 parts by weight of methyltrimethoxysilane, and 21.6 parts by weight of tetraethoxysilane, along with 20 parts by weight of distilled water and 5 parts by weight of propylene glycol monomethyl ether acetate (PGMEA) relative to their total weight, followed by refluxing and vigorously stirring the mixture for 7 hours in the presence of 0.1 part by weight of an oxalic acid catalyst. Then, the mixture was cooled and diluted with PGMEA such that the solids content was 40%, and it was analyzed by GPC. As a result, a siloxane copolymer (A-1) having a weight average molecular weight of 5,000 to 15,000 Da referenced to a polystyrene standard was prepared. The acid dissociation constant of the siloxane copolymer (A-1) thus prepared was 7.5.

### [Synthesis Example 2] Preparation of a Siloxane Copolymer (A-2)

A reactor equipped with a reflux condenser was charged with 50.2 parts by weight of phenyltrimethoxysilane, 16.6 parts by weight of methyltrimethoxysilane, 14.8 parts by weight of dimethyldimethoxysilane, and 18.4 parts by weight of tetraethoxysilane, along with 20 parts by weight of distilled water and 5 parts by weight of propylene glycol monomethyl ether acetate (PGMEA) relative to their total weight, followed by refluxing and vigorously stirring the mixture for 7 hours in the presence of 0. 1 part by weight of an oxalic acid catalyst. Then, the mixture was cooled and diluted with PGMEA such that the solids content was 53%, and it was analyzed by GPC. As a result, a siloxane copolymer (A-2) having a weight average molecular weight of 5,000 to 15,000 Da referenced to a polystyrene standard was prepared. The acid dissociation constant of the siloxane copolymer (A-2) thus prepared was 7.6.

### [Synthesis Example 3] Preparation of a Siloxane Copolymer (A-3)

A reactor equipped with a reflux condenser was charged with 23.6 parts by weight of phenyltrimethoxysilane, 7.8 parts by weight of methyltrimethoxysilane, and 68.6 parts by weight of diphenyldimethoxysilane, along with 11 parts by weight of distilled water and 30 parts by weight of propylene glycol monomethyl ether acetate (PGMEA) relative to their total weight, followed by refluxing and vigorously stirring the mixture for 4 hours in the presence of 0.5 part by weight of an sulfuric acid catalyst. Then, the mixture was cooled and diluted with PGMEA such that the solids content was 40%, and it was analyzed by GPC. As a result, a siloxane copolymer (A-3) having a weight average molecular weight of 500 to 5,000 Da referenced to a polystyrene standard was prepared. The acid dissociation constant of the siloxane copolymer (A-3) thus prepared was 11.5.

### [Synthesis Example 4] Preparation of an Acrylic Copolymer (H)

A flask equipped with a cooling tube and a stirrer was charged with 200 parts by weight of propylene glycol monomethyl ether acetate as a solvent, and the temperature of the solvent was raised to 70° C. while the solvent was stirred slowly. Added thereto were 17.7 parts by weight of methacrylic acid, 20.7 parts by weight of glycidyl methacrylate, 20.4 parts by weight of styrene, 29.4 parts by weight of methyl methacrylate, and 11.8 parts by weight of methacrylate, followed by dropwise adding of 3 parts by weight of 2,2′-azobis(2,4-dimethylvaleronitrile) as a radical polymerization initiator over 5 hours to carry out a polymerization reaction, thereby preparing an acrylic copolymer having a solids content of 32% by weight. The acrylic copolymer thus prepared was subjected to GPC analysis, and its weight average molecular weight referenced to a polystyrene standard was confirmed to be 10,000 Da.

### [Example 1] Preparation of a Photosensitive Resin Composition

Based on the solids content, 100 parts by weight of a mixture, in which 26.6 parts by weight of the siloxane copolymer (A-1) synthesized in Synthesis Example 1 and 73.4 parts by weight of the siloxane copolymer (A-2) synthesized in Synthesis Example 2 had been mixed, was homogeneously mixed with 11.68 parts by weight of a resin (B) comprising a structural unit represented by Formula 1, 13.16 parts by weight of a photoactive compound (C), 29.83 parts by weight of an epoxy compound (F), and 0.39 part by weight of a surfactant (G). It was dissolved in a solvent (D) in which propylene glycol monomethyl ether acetate (PGMEA) (D-1) and gammabutyrolactone (GBL) (D-2) had been mixed at a weight ratio of 93:7 such that the solids content thereof was 17% by weight. It was then stirred for 1 to 2 hours and filtered through a membrane filter having a pore diameter of 0.2 µm to obtain a photosensitive resin composition having a solids content of 17% by weight.

### [Examples 2 to 10] Preparation of a Photosensitive Resin Composition

A photosensitive resin composition was prepared in the same manner as in Example 1, except that its composition was changed shown in Tables 1 and 2.

### [Comparative Example 1 to 3] Preparation of a Photosensitive Resin Composition

A photosensitive resin composition was prepared in the same manner as in Example 1, except that its composition was changed shown in Tables 1 and 2. In such an event, in Comparative Example 3, other components were mixed relative to 100 parts by weight of a mixture in which the siloxane copolymer (A-1) synthesized in Synthesis Example 1 (A-1), the siloxane copolymer (A-2) synthesized in Synthesis Example 2 (A-2), and/or the acrylic copolymer (H) synthesized in Synthesis Example 4 had been mixed.

TABLE 1

| | Siloxane copolymer (A) | | | Resin containing a repeat unit represented by Formula 1 (B) | |
|---|---|---|---|---|---|
| | A-1 (pKa: 7.5) | A-2 (pKa: 7.6) | A-3 (pKa: 11.5) | B-1 (ZAR-2001H, Nippon Kayaku) | B-2 (ZFR-1491H, Nippon Kavaku) |
| Ex. 1 | 26.60 | 73.40 | - | 11.68 | - |
| Ex. 2 | 26.60 | 73.40 | - | 27.09 | - |
| Ex. 3 | 26.60 | 73.40 | - | - | 11.39 |
| Ex. 4 | 26.60 | 73.40 | - | - | 26.42 |
| Ex. 5 | 26.60 | 73.40 | - | 12.54 | - |
| Ex. 6 | 26.60 | 73.40 | - | 3.50 | - |
| Ex. 7 | 26.60 | 73.40 | - | 5.84 | - |
| Ex. 8 | 26.60 | 73.40 | - | 3.32 | - |
| Ex. 9 | 30.79 | 69.21 | - | 10.28 | - |
| Ex. 10 | 10.75 | 17.90 | 71.34 | 9.97 | - |
| C. Ex. 1 | 26.60 | 73.40 | - | - | - |
| C. Ex. 2 | 26.60 | 73.40 | - | - | - |
| C. Ex. 3 | 10.78 | 44.85 | - | - | - |

TABLE 2

| | Photoactive compound (C) | Solvent (D) | | Photopolymerizable compound (E) | Epoxy compound (F) | Surfactant (G) | Acrylic Copolymer (H) |
|---|---|---|---|---|---|---|---|
| | Quinonediazide compound (TPA-517, Miwon) | D-1 (PGMEA) | D-2 (GBL) | DPCA-120 (Nippon Kayaku) | GHP03HP (Miwon) | FZ-2122 (Dow Coming Toray) | |
| Ex. 1 | 13.16 | 93.00 | 7.00 | - | 29.83 | 0.39 | - |
| Ex. 2 | 15.27 | 93.00 | 7.00 | - | 29.83 | 0.45 | - |
| Ex. 3 | 13.16 | 93.00 | 7.00 | - | 29.83 | 0.41 | - |
| Ex. 4 | 15.27 | 93.00 | 7.00 | - | 29.83 | 0.48 | - |
| Ex. 5 | 14.14 | 93.00 | 7.00 | - | 29.83 | 0.44 | - |
| Ex. 6 | 13.16 | 93.00 | 7.00 | 4.16 | 29.83 | 0.41 | - |
| Ex. 7 | 13.16 | 93.00 | 7.00 | 5.42 | 29.83 | 0.41 | - |
| Ex. 8 | 12.47 | 93.00 | 7.00 | 3.87 | 29.83 | 0.39 | - |
| Ex. 9 | 11.58 | 93.00 | 7.00 | 2.20 | - | 0.36 | - |
| Ex. 10 | 11.24 | 93.00 | 7.00 | - | 25.46 | 0.35 | - |
| C. Ex. 1 | 11.57 | 93.00 | 7.00 | - | 29.83 | 0.36 | - |
| C. Ex. 2 | 13.16 | 93.00 | 7.00 | - | 29.83 | 0.41 | - |
| C. Ex. 3 | 9.89 | 93.00 | 7.00 | 7.74 | 25.51 | 0.31 | 44.38 |

### [Test Example 1] Evaluation of Sensitivity

The photosensitive resin compositions prepared in the Examples and the Comparative Examples were each coated onto a glass substrate by spin coating. It was then pre-baked on a hot plate kept at 110° C. for 90 seconds to form a dried film. The dried film thus formed was exposed to light through a mask having a pattern of square holes in a size ranging from 1 to 30 µm at an exposure dose of 0 to 200 mJ/cm² based on a wavelength of 365 nm for a certain time period using an aligner (model name: MA6) that emits light having a wavelength of 200 nm to 450 nm with a gap of 25 µm between the mask and the substrate. Next, it was developed with an aqueous developer of 2.38% by weight of tetramethylammonium hydroxide through puddle nozzles at 23° C. for 60 seconds. Next, it was exposed to light at an exposure dose of 200 mJ/cm² based on 365 nm for a certain time period using an aligner (model name: MA6) that emits light having a wavelength of 200 nm to 450 nm (i.e., bleaching step) and then heated in a convection oven at 250° C. for 30 minutes to prepare a cured film having a thickness of 2 µm.

For the hole pattern formed through a mask having a size of 10 µm, the amount of exposure energy required for attaining a critical dimension (CD, unit: µm) of 10 µm was measured to evaluate sensitivity. The results are shown in Table 3 below.

The smaller the measured value of sensitivity (mJ/cm²), the more excellent. It is preferably 150 mJ/cm² or less.

### [Test Example 2] Evaluation of Flexible Characteristics

The photosensitive resin compositions prepared in the Examples and Comparative Examples were each coated onto a glass substrate coated with a polyimide film by spin coating. It was then pre-baked on a hot plate kept at 110° C. for 90 seconds to form a dried film. The dried film thus formed was developed with an aqueous developer of 2.38% by weight of tetramethylammonium hydroxide through puddle nozzles at 23° C. for 60 seconds. Next, it was exposed to light at an exposure dose of 200 mJ/cm² based on 365 nm for a certain time period using an aligner (model name: MA6) that emits light having a wavelength of 200 nm to 450 nm (i.e., bleaching step) and then heated in a convection oven at 250° C. for 30 minutes to prepare a cured film having a thickness of 2 µm Then, the cured film and the polyimide film were detached from the glass substrate, and a dynamic folding test was performed using folding test equipment (model name: foldy-10-1U) Specifically, it was folded 200,000 times in the out-folding direction at a radius of curvature of 1R, and cracks on the cured film were then checked. If no cracks were observed, it was evaluated as “○” If cracks were observed, it was evaluated as “x” The results are shown in Table 3 below and the FIGURE.

If no cracks were observed, it was evaluated to be excellent in flexibility.

### [Test Example 3] Evaluation of Film Retention Rate

The photosensitive resin compositions prepared in the Examples and Comparative Examples were each coated onto a glass substrate by spin coating. It was then pre-baked on a hot plate kept at 110° C. for 90 seconds to form a dried film. Next, it was developed with an aqueous developer of 2.38% by weight of tetramethylammonium hydroxide through puddle nozzles at 23° C. for 60 seconds. Next, it was exposed to light at an exposure dose of 200 mJ/cm² based on 365 nm for a certain time period using an aligner (model name: MA6) that emits light having a wavelength of 200 nm to 450 nm (i.e., bleaching step) and then heated (post-baked) in a convection oven at 250° C. for 30 minutes to prepare a cured film having a thickness of 2 µm.

In the course of forming the cured film, the thickness of the film obtained after pre-bake and the thickness of the film obtained after post-bake were measured with a film thickness evaluation device (SNU Precision), and the film retention rate of the cured film was calculated by the following equation. The results are shown in Table 3 below.

$$\begin{matrix}\text{Film} \text{retention} \text{rate} \left(\%\right) = \\ \left(\text{film} \text{thickness} \text{after} \text{post-break} \text{/} \text{film} \text{thickness} \text{after} \text{pre-}\right) \\ \left(\text{bake}\right) \times 100\end{matrix}$$

The larger the measured value of film retention rate (%), the more excellent. It is preferably 80% or more.

TABLE 3

| | Sensitivity (mJ/cm²) | Flexible characteristics | Film retention rate (%) |
|---|---|---|---|
| Ex. 1 | 95 | ○ | 91.6 |
| Ex. 2 | 100 | ○ | 80.8 |
| Ex. 3 | 90 | ○ | 90.1 |
| Ex. 4 | 100 | ○ | 81.2 |
| Ex. 5 | 80 | ○ | 90.1 |
| Ex. 6 | 55 | ○ | 90.6 |
| Ex. 7 | 60 | ○ | 95.3 |
| Ex. 8 | 75 | ○ | 95.4 |
| Ex. 9 | 55 | ○ | 80.4 |
| Ex. 10 | 250 | ○ | 78.8 |
| C. Ex. 1 | 70 | X | 95.5 |
| C. Ex. 2 | 50 | X | 85.5 |
| C. Ex. 3 | 80 | X | 84.9 |

Referring to Table 3 and the FIGURE, when a cured film was formed from the photosensitive resin compositions of the Examples in which the resin (B) containing a structural unit represented by Formula 1 had been employed, the sensitivity and film retention rate, as well as the flexible characteristics, were excellent. In contrast, when a cured film was formed from the photosensitive resin composition of the Comparative Examples in which the resin (B) had not been employed, the flexible characteristics were remarkably deteriorated.

1. A positive-type photosensitive resin composition, which comprises:
(A) a siloxane copolymer;
(B) a resin comprising a structural unit represented by the following Formula 1;
(C) a photoactive compound, and
(D) a solvent: 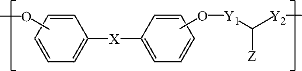
in Formula 1,
X is a substituted or unsubstituted C₁₋₆ aliphatic structure,
Y₁ and Y₂ are each independently a substituted or unsubstituted C₁₋₆ alkylene group or a substituted or unsubstituted C₄₋₁₀ cycloalkylene group, and
Z is hydrogen, a substituted or unsubstituted C₁₋₆ alkyl group, or a substituent represented by the following Formula 1a, 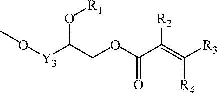
in Formula 1a,
Y₃ is a substituted or unsubstituted C₁₋₆ alkylene group or a substituted or unsubstituted C₄₋₁₀ cycloalkylene group,
R₁ is hydrogen or a substituent represented by the following Formula 1b, and
R₂ to R₄ are each independently hydrogen, a substituted or unsubstituted C₁₋₁₀ alkyl group, or a substituted or unsubstituted C₆₋₁₅ aryl group, 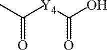
in Formula 1b,
Y₄ is a substituted or unsubstituted C₁₋₆ alkylene group or a substituted or unsubstituted C₄₋₁₀ cycloalkylene group.

2. The positive-type photosensitive resin composition of claim 1, wherein the siloxane copolymer has an acid dissociation constant (pKₐ) of 11 or less in dimethyl sulfoxide.

3. The positive-type photosensitive resin composition of claim 1, wherein the siloxane copolymer (A) has a weight average molecular weight of 3,000 to 20,000 Da.

4. The positive-type photosensitive resin composition of claim 1, wherein the siloxane copolymer (A) comprises a structural unit derived from two or more silane compounds represented by the following Formula 2: 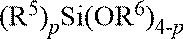
in Formula 2,
p is an integer of 0 to 3,
R⁵ is each independently a C₁₋₁₂ alkyl group, a C₂₋₁₀ alkenyl group, a C₆₋₁₅ aryl group, a 3- to 12-membered heteroalkyl group, a 4- to 10-membered heteroalkenyl group, or a 6- to 15-membered heteroaryl group,
R⁶ is each independently hydrogen, a C₁₋₅ alkyl group, a C₂₋₆ acyl group, or a C₆₋₁₅ aryl group, and
the heteroalkyl, the heteroalkenyl, and the heteroaryl groups each independently have at least one heteroatom selected from the group consisting of O, N, and S.

5. The positive-type photosensitive resin composition of claim 4, wherein the siloxane copolymer (A) comprises the structural unit derived from the silane compound of the above Formula 2 where p is 2 in an amount of 5 to 40% by mole relative to the number of moles of Si atoms.

6. The positive-type photosensitive resin composition of claim 1, which comprises the resin (B) in an amount of 2 to 40 parts by weight relative to 100 parts by weight of the siloxane copolymer (A) on the basis of solids content.

7. The positive-type photosensitive resin composition of claim 1, wherein, in Formula 1,
X is a substituted or unsubstituted C₁₋₆ alkylene group,
Y₁ and Y₂ are each independently a C₁₋₃ alkylene group,
Z is a substituent represented by Formula 1a, wherein Y₃ is a C₁₋₃ alkylene group, R₁ is a substituent represented by Formula 1b in which Y₄ is a C₄₋₇ cycloalkylene group, and R₂ to R₄ are all hydrogen.

8. The positive-type photosensitive resin composition of claim 1, which further comprises at least one of (E) a photopolymerizable compound comprising a double bond; and (F) an epoxy compound.

9. The positive-type photosensitive resin composition of claim 8, which comprises, based on the total weight of the positive-type photosensitive resin composition,
15% by weight to 35% by weight of the siloxane copolymer (A);
0.1 to 15% by weight of the resin (B);
0.1 to 20% by weight of the photoactive compound (C),
0.1 to 10% by weight of the photopolymerizable compound (E);
0.1 to 20% by weight of the epoxy compound (F); and
the balanced amount of the solvent (D).

10. A cured film prepared from the positive-type photosensitive resin composition of claim 1.
